(19) United States
(12) Patent Application Publication
(10) Pub. No.: US 2020/0402793 A1
(43) Pub. Date: Dec. 24, 2020

(54) A METHOD FOR CREATING STRUCTURES OR DEVICES USING AN ORGANIC ICE RESIST

(71) Applicant: Danmarks Tekniske Universitet, Kgs. Lyngby (DK)

(72) Inventors: Anpan HAN, Bagsvaerd (DK); William TIDDI, Frederlksberg (DK); Marco BELEGGIA, Potsdam (DE)

(73) Assignee: Danmarks Tekniske Universitet, Kgs. Lyngby (DK)

(21) Appl. No.: 16/097,744

(22) PCT Filed: May 1, 2017
(86) PCT No.: PCT/EP2017/060313

§ 371 Date: Oct. 30, 2018

(30) Foreign Application Priority Data
May 2, 2016 (EP) 16167903.0

(51) Int. Cl. H01L 21/027; H01J 37/317; H01L 21/3065; H01L 21/308

(52) U.S. Cl. CPC H01L 21/0273; H01J 37/3174; H01J 2237/31794; H01L 21/308; H01L 21/3065

(57) ABSTRACT

The invention relates to a method for creating an organic resist on a surface of a cooled substrate, the method comprising the steps of condensing a vapour into a solid film on the surface of the cooled substrate; patterning at least part of the solid film by exposing selected portions of said solid film to at least one electron beam thereby creating the organic resist on 5 the surface of the cooled substrate in accordance with a predetermined pattern; wherein the created organic resist remains essentially intact at ambient conditions; and using the created organic resist as a mask for creating semiconductor structures and/or semiconductor devices.

### FIELD OF THE INVENTION

The present invention relates to a method for creating semiconductor structures and/or devices using an organic ice resist that remains essentially intact at ambient conditions. According to the method of the present invention vapours of simple organic molecules, such as short hydrocarbons or common organic solvents, condense to ice layers, i.e. an organic ice resist, which can be exposed to electron beam patterning.

### BACKGROUND OF THE INVENTION

The key enabling technology in the semiconductor industry is lithography to pattern billions of transistors in a computer chip. Electron Beam Lithography (EBL) and extreme ultra violet (EUV) lithography are the two main competing technologies for the fabrication of future computer chips. In EBL, finely focused electron beams (1 nm diameter) pattern a resist material. The resist is typically made of organic macromolecules larger than several nm in size leading to the smallest achievable patterns which are much larger than the beam diameter, thus limiting the application of EBL for future technology nodes which tend to be smaller and smaller.

The archetypical EBL resist is the polymeric material polymethylmethacrylate (PMMA) with a molecular weight of 950 kDa. Upon electron irradiation, chemical bonds are broken and generate smaller (few kDa) polymer molecules. During development in an organic solvent, smaller molecules swell and dissolve in the solvent, while larger molecules remain. The physical dimensions of the swelled small polymers determine the smallest features that can be patterned in PMMA. Because chemical bonds cannot be broken in a perfect straight line, the edges of patterns are rough on the nanometer scale, which is referred to as the Line Edge Roughness (LER). Hence, even if the patterning electron beam diameter is less than 1 nm, the smallest feature size in PMMA is above 10 nm, and the LER is a few nm.

Molecules of resists of condensed gases can be much smaller than the polymer resists and therefore sharper bond-breaking processes will occur during the exposure to a focused electron beam. This may result in a substantially improved quality of the resulting patterns. A process where water vapour is condensed onto a sample is known in the art. The sample is cooled down to −160° C., and the resulting ice is utilized as an EBL resist. Thanks to the low molecular weight of water, realized patterns are significantly smaller than 10 nm, opening a new path for making next generation computer chips. However, ice melts at ambient conditions, and therefore the method is not compatible with other semiconductor manufacturing and test equipment that operate at ambient conditions.

It may be seen as an object of embodiments of the present invention to provide an advanced group of resists which, after exposure to EBL, are essentially intact and stable at ambient conditions.

It may be seen as a further object of embodiments of the present invention to provide solid structures on the sub 10 nm scale and at the same time provide a roughness of the pattern edges being smaller than 1 nm.

### DESCRIPTION OF THE INVENTION

The above-mentioned objects are complied with by providing, in a first aspect, a method for creating a solid structure on a surface of a cooled substrate, the method comprising the steps of
1) condensing a vapour into a solid film on the surface of the cooled substrate; and
2) patterning at least part of the solid film by exposing selected portions of said solid film to at least one electron beam thereby creating the solid structure on the surface of the cooled substrate in accordance with a predetermined pattern;

wherein the created solid structure remains essentially intact at ambient conditions.

In the present context condensing should be understood as transforming a compound from a fluid phase to a solid phase.

Finally, the term “essentially intact” should be understood as essentially unmodified. Thus, by stating that the solid structure remains essentially intact it means that the solid structure remains unchanged in terms of chemical properties as well as the state of matter when exposed to ambient conditions, such as room temperature.

Naturally, a potential candidate for the vapour is to be condensable under certain circumstances. Typically, the vapour comprises molecules with a molecular mass smaller than 100 Daltons. The vapour may be created from one or more of the compounds which can be selected from the compounds mentioned in the following text books: Landolt-Börnstein: New Series, Neue Serie Group 4 Vol. 20a: Vapor Pressure of Chemicals, Landolt-Börnstein: New Series, Neue Serie Group 4 Vol. 20b: Vapor Pressure of Chemicals, Landolt-Börnstein: New Series, Neue Serie Group 4 Vol. 20c: Vapor Pressure of Chemicals and National Institute of Standards and Technology NIST WebBook.

The compounds from the above mentioned references that may be used as a potential candidate for the vapour may need to fulfil a number of conditions. These conditions may include appropriate vapour pressure at 150 K, appropriate vapour pressure at room temperature and appropriate vapour pressure at e.g. 100° C. These may be calculated from the Antoine equation. Reference value for all three pressure values may be water. The vapour pressure at 150 K may need to be low, preferably the same or lower than vapour pressure of water at 150 K which is 4.7e-10 Torr. Furthermore, this pressure may need to be lower than the vacuum pressure in a chamber where the compound is to be frozen (5e-6 Torr). The vapour pressure of the possible compounds at room temperature (298 K) needs to be similar to that of water which is 23 Torr. Preferably between 1 Torr and 760 Torr. If the vapour pressure of the compound at room temperature is too low, then it may not be possible to heat the compound to higher temperature, e.g. 100° C. and hence create higher vapour pressure and inject it into the chamber.

Furthermore, potential candidates for the vapour may belong to certain classes of chemicals. These classes may be: hydrocarbon C₆-C₁₆, sulfur containing compounds, halogen containing compounds, oxygen containing compounds, nitrogen containing compounds, monomers, and ALD and CVD precursors for metallic layers. Some of the compounds selected from these classes are listed in Table 1 below.

Vapour parameters which are of relevance for the solid film creation are 1) vapour pressure at 150 K, 2) vapour pressure at 298 K, 3) triple point, 4) ionization cross-section at 10 keV and 5) ionization cross-section at 50 keV. Parameters such as vapour pressure at 150 K, vapour pressure at room temperature (298 K), and a vapour pressure at 100° C. are listed in a Table 1 below. The values for the vapour pressure are estimated with Antoine equation. A product of reaction between the vapour and an electron beam may be solid.

TABLE 1

| | Vapour pressure at | Vapour pressure | Vapour pressure |
|---|---|---|---|
| Substance | 150 K (Torr) | at 298 K (Torr) | at 100° C. |
| Hydrocarbon C₆—C₁₆ | | | |
| Styrene | 2.3077E−09 | 5.773067627 | 176.2174522 |
| Naphtahalene | 1.09233E−15 | 0.219129087 | 17.24450241 |
| Decane (l) | 1.62471E−09 | 1.361723841 | 75.52514477 |
| Undecane | 4.33112E−17 | 2.563681564 | 212.3951506 |
| Sulfur containing | | | |
| compounds | | | |
| DMSO, | 7.21763E−12 | 0.623149877 | 40.07336622 |
| dimethylsulfoxide | | | |
| Cyclohexanethiol | 8.33755E−11 | 3.96703031 | 130.9172118 |
| Sulfur trioxide | 7.36621E−13 | 310.2552461 | |
| Halogen containing | | | |
| compounds | | | |
| Bromine trifluoride | 1.98599E−10 | 7.387608739 | 302.375888 |
| Xenon difluoride | 3.74027E−10 | 3.362243848 | 290.7093857 |
| Iodine | 6.15978E−13 | 0.250654554 | 37.68696869 |
| Hexachloropropene | 4.46385E−17 | 0.221503656 | 18.45940617 |
| C₁₀F₁₈ | 6.04962E−12 | 6.163955145 | 209.5897252 |
| Oxygen containing | | | |
| compounds | | | |
| Chlorine trioxide | 7.5E−09 | 1.697852557 | 34.72929268 |
| Water | 3.40519E−08 | 23.66483109 | 760.3501647 |
| 1-Propanol | 4.55191E−11 | 21.36026901 | 858.7856775 |
| 1-Pentanol | 1.60433E−24 | 1.906763656 | 178.8565595 |
| Methoxybenzene/anisole | 2.9212E−12 | 3.397280754 | 139.7881973 |
| Nitrogen containing | | | |
| compounds | | | |
| Nitropropane | 2.01667E−09 | 9.821293764 | 280.4790192 |
| Monomers | | | |
| Styrene | 5.04474E−10 | 6.174580853 | 242 |
| ALD and CVD | | | |
| precursors for metalic | | | |
| layers | | | |
| Trimethylaluminum | 9.72E−08 | 10.426353 | |
| Diethylzinc | 4.11331E−07 | 20.0298286 | |

Typically, the vapour may be introduced into the high vacuum chamber via a gas injection system which may comprise a nozzle designed to control the vapour flow as it enters the vacuum chamber. Once the vapour gets in contact with the cooled substrate it will be condensed into a solid film.

The substrate may have a planar surface, but may as well have a surface which is nonplanar. Despite the nonplanar surface of the substrate the solid film will stick to the surface due to a good adhesion between the surface of the substrate and vapour deposited. Typically, the substrate may comprise a wafer, such as a standard 100 mm wafer. The wafer material may be silicon or other types of materials.

The substrate may be cooled to temperatures below 200 K, such as below 170, such as below 150K, such as below 130 K, such as below 110 K, such as below 90 K, such as around 70 K. In order to cool the substrate a cryogenic system arranged in a high vacuum chamber may be used.

Typically, high-vacuum chambers operate at pressures of around 10⁻⁶ Torr. Preferably, the vapour has a pressure which is on the order of 0.1-10 Torr at room temperature so that it can be introduced into the vacuum chamber via the above-mentioned gas injection system.

The cryogenic system may consist of a copper base that is cooled by thermal contact through an oxygen-free copper braid. The copper braid may be soldered or clamped to a cryogenic stage. The other end of the copper braid may also be either soldered or clamped onto a copper rod that may be immersed in a liquid-nitrogen, LN₂, which may be held in an external LN₂ dewar.

Once condensed, the solid film preferably has a vapour pressure smaller than the pressure in the high vacuum chamber in order to prevent sublimation. A thickness of the solid film may be controlled both by controlling the temperature of the cryogenic stage and by controlling the amount of vapour introduced to the vacuum chamber. Typically, the thickness of the solid film may be a number of monolayers. For example, less than 20 monolayers may be grown on the substrate at temperatures smaller than 130 K in 30 minutes. The solid film may be sustainable because the chemicals used for its formation are typically inexpensive and non-hazardous substances.

The next step involves patterning of at least part of the solid film formed. In this step, the physical dimensions and locations of final devices may be defined. The patterning is performed in accordance with a predetermined pattern which defines distinct features which are to be formed into the underlying substrate. In one embodiment of the invention, the patterning creates the solid structure on the surface of the cooled substrate. The patterning may be performed by electron beam lithography, i.e. by exposing selected portions of the solid film to at least one electron beam. Other suitable techniques may also involve extreme ultraviolet (EUV) lithography or scanning probe microscope lithography techniques such as scanning tunnelling microscope.

An electron beam is considered a stable and well-focused beam of electrons with a high beam current and high energy. The electron beam may change the chemical structure and thereby the chemical composition of the exposed regions of the solid film. According to the invention, the solid film interacts with energetic electrons in a way so that the resulting product, i.e. one or more solid structures, remains essentially intact and stable under ambient conditions, i.e. when the one or more solid structures are brought to for example room temperatures. The electron energy may be between 1 keV and 30 keV, such as between 5 keV and 20 keV. There are also secondary electrons generated through in-elastic electron matter interactions. The secondary electrons may have an energy up to 50 eV. Both energies need to be larger than the few eV what is needed to ionize electrons in the outer shell in most atoms comprised in the solid film.

Typically, the number of electrons per unit surface which are required to expose the solid film, the so-called clearance dose, may be less than 50 μC/cm². This dose is at least four times smaller than that required for standard, commercially used patterning. The sensitivity of the solid film may be higher as the ionization cross-section (Table 1) given by the Bethe equation is also higher. The sensitivity of the solid film also depends on whether or not the solid film reacts in an avalanche chain reaction initiated by a single electron. Since the clearance dose is typically very low, the substrate under the solid film will not be damaged during the patterning process.

Electron beam writing time depends on a number of parameters such as a dose, area to be exposed and an electron beam current. As mentioned above, typically the dose is four times lower than that required for standard electron beam exposure. Therefore, the writing time is expected to be at least four times shorter than the time of a standard beam exposure.

The solid structure is created through a chemical reaction between the molecules comprised in the solid film and the electron beam while the solid film being kept in a high vacuum chamber at low temperature. Namely, an energetic electron beam locally changes the chemical properties and structure of the solid film thereby changing the chemical composition of the exposed regions of the solid film, creating tight bonds between the atoms comprised in the solid film, thereby forming the solid structures. Typically, the molecules comprised in the solid film react in an avalanche chain reaction initiated by a single electron creating free radicals which further react with each other in a radical polymerization reaction.

As mentioned above, the solid structure created remains essentially intact when being exposed to ambient conditions thanks to tight chemical bonds formed between the atoms comprised in the solid film while the unexposed parts of the solid film will sublimate. Ambient conditions may typically refer to a normal, uncontrolled atmospheric pressure, room temperature and normal humidity values. These conditions may typically be fulfilled as soon as the sample is withdrawn from the vacuum chamber, i.e. taken outside the vacuum chamber.

A roughness of the edges of the created solid structure may be less than 10 nm, such as less than 8 nm, such as less than 6 nm, such as less than 4 nm, such as less than 2 nm, such as less than 1 nm.

A half-pitch of the created structure may be less than 50 nm, such as less than 40 nm, such as less than 30 nm, such as less than 20 nm, such as less than 10 nm. Half-pitch or technology node is a measure for how densely devices can be packed together, i.e. it determines half the distance between the two identical patterns. By obtaining that the half-pitch is less than 10 nm and the LER is smaller than 1 nm, the smallest features to be achieved are also smaller than 10 nm. LER may be highly dependent on the molecular weight of the vapour used. The interaction between the electron beam and the solid film determines the smallest pattern, and it depends on the forward scattering angle of electrons upon impact with the solid film substance, solid film thickness, sample temperature, penetration depth of energetic electrons, etc.

In one embodiment of the present invention, the solid structure created may be used as a resist mask for transferring the solid structure created to either the underlying substrate or another solid film being positioned between the solid structure and the substrate. The solid structure created may be transferred to the underlying substrate or solid film using, for example, an etching process, such as reactive ion etching, inductively coupled plasma reactive ion etching, ion sputtering and ion beam milling. The solid structure may also be slightly etched during the transfer process. The ratio of the substrate etch rate to the solid film consumption rate defines the etch selectivity, and may be optimized through carefully tuning parameters such as sample temperature, gas combinations and flow, and ion beam power. The etch selectivity between patterned solid structures and the substrate may be larger than 1:5.

The final step involves the removal of the solid structure created which was only slightly etched during the transfer process. The solid structure may be removed without harming the underlying substrate. The result is a final structure which may be a functional device.

According to a second aspect, the present invention relates to a method for creating a 3D solid structure on a surface of a cooled substrate, the method involves repeating the following process steps 1), 2) and 3) a plurality of times:
1) condensing a vapour into a solid film on the surface of the cooled substrate;
2) patterning at least part of the solid film by exposing selected portions of said solid film to at least one electron beam thereby creating the solid structure on the surface of the cooled substrate in accordance with a predetermined pattern; and
3) evaporating unexposed parts of the solid film.

Thus, the process steps 1), 2) and 3) may be considered forming a process loop where a given solid film is formed, exposed at selected portions and subsequently developed by letting the unexposed parts of the solid film evaporate. Depending on the complexity of the 3D solid structure to be manufactured the process loop may be repeated the required number of times. The final 3D solid structure may in principle be of any complexity. Naturally, more complex patterns require larger number of steps compared to a simple one.

The vapour, the solid film as well as the exposure of the solid film may be implemented as disclosed in relation to the first aspect of the present invention. It should be noted however that the process loops may involve different vapours so that a first type of vapour (an organic vapour for example) may be condensed in a first loop whereas a second type of vapour (a non-organic vapour for example) may be condensed in a second loop.

According to a third aspect, the present invention relates to a method for creating a 3D solid structure on a surface of a cooled substrate, the method involves repeating process steps 1) and 2) a plurality of times:
1) condensing a vapour into a solid film on the surface of the cooled substrate; and
2) patterning at least part of the solid film by exposing selected portions of said solid film to at least one electron beam thereby creating the solid structure on the surface of the cooled substrate in accordance with a predetermined pattern; and
3) evaporating all unexposed parts of the solid film.

Thus, in contrast to the method of the second aspect evaporation of all the unexposed parts may be performed in a single process step at the very end. In other words the process steps 1) and 2) may be considered forming a process loop where a given solid film is formed and subsequently exposed at selected portions. Depending on the complexity of the 3D solid structure to be manufactured the process loop may be repeated the required number of times.

Again, the vapour, the solid film as well as the exposure of the solid film may be implemented as disclosed in relation to the first aspect of the present invention. It should be noted however that the process loops may involve different vapours so that a first type of vapour (an organic vapour for example) may be condensed in a first loop whereas a second type of vapour (a non-organic vapour for example) may be condensed in a second loop.

The solid film created in one step may not interact with a new layer of vapour which may be applied in the following step. These steps may be performed in the high vacuum chamber at low temperatures. Once the desired 3D solid structure has been created by using for example electron-beam writing, the structure may be taken out from the high vacuum chamber and all unexposed parts of the solid film will evaporate leaving the desired 3D solid structure.

Furthermore, it is possible to scale up the entire process and to adapt a created solid structure to be used in a massive production.

According to a fourth aspect the present invention relates to a method for creating an organic resist on a surface of a cooled substrate, the method comprising the steps of
1) condensing a vapour into a solid film on the surface of the cooled substrate;
2) patterning at least part of the solid film by exposing selected portions of said solid film to at least one electron beam thereby creating the organic resist on the surface of the cooled substrate in accordance with a predetermined pattern; wherein the created organic resist remains essentially intact at ambient conditions; and
3) using the created organic resist as a mask for creating semiconductor structures and/or semiconductor devices.

Similar to the first aspect the term “condensing” should be understood as transforming a compound from a fluid phase to a solid phase. In addition, the term “essentially intact” should be understood as essentially unmodified. Thus, by stating that the created organic resist remains essentially intact means that the organic resist remains unchanged in terms of chemical properties as well as the state of matter when exposed to ambient conditions, such as room temperature. As the substrate is cooled, cf. details below, the organic resist may be considered an organic ice resist.

The potential candidates for generating the vapour may be similar to those addressed in connection with the first aspect, including one or more of the following classes of chemicals: hydrocarbon C6-C16, sulfur containing compounds, halogen containing compounds, oxygen containing compounds, nitrogen containing compounds, monomers, and ALD and CVD precursors for metallic layers. Moreover, the vapour parameters addressed in connection with the first aspect generally also apply in connection with this fourth aspect.

Similar to the first aspect, the vapour may be introduced into the high vacuum chamber via a gas injection system which may comprise a nozzle designed to control the vapour flow as it enters the vacuum chamber. Once the vapour gets in contact with the cooled substrate it will be condensed into a solid film.

The substrate may have a planar surface, but may as well have a surface which is nonplanar. Despite the nonplanar surface of the substrate the solid film will stick to the surface due to a good adhesion between the surface of the substrate and vapour deposited. Typically, the substrate may comprise a wafer, such as a standard 100 mm wafer. The wafer material may be silicon or other types of materials.

The substrate may be cooled to temperatures below 200 K, such as below 170, such as below 150K, such as below 130 K, such as below 110 K, such as below 90 K, such as around 70 K. In order to cool the substrate a cryogenic system arranged in a high vacuum chamber may be used.

The semiconductor structures and/or the semiconductor devices may be created in the underlying substrate. The underlying substrate may comprise a semiconductor substrate, such as a silicon substrate.

As addressed above high vacuum chambers typically operate at pressures of around 10-6 Torr. Preferably, the vapour has a pressure which is on the order of 0.1-10 Torr at room temperature so that it can be introduced into the vacuum chamber via the above-mentioned gas injection system.

The cryogenic system may consist of a copper base that is cooled by thermal contact through an oxygen free copper braid. The copper braid may be soldered or clamped to a cryogenic stage. The other end of the copper braid may also be either soldered or clamped onto a copper rod that may be immersed in a liquid nitrogen, LN2, which may be held in an external LN2 dewar.

Once condensed, the solid film preferably has a vapour pressure smaller than the pressure in the high vacuum chamber in order to prevent sublimation. A thickness of the solid film may be controlled both by controlling the temperature of the cryogenic stage and by controlling the amount of vapour introduced to the vacuum chamber. Typically, the thickness of the solid film may be a number of monolayers. For example, less than 20 monolayers may be grown on the substrate at temperatures smaller than 130 K in 30 minutes. The solid film may be sustainable because the chemicals used for its formation are typically inexpensive and non-hazardous substances.

The next step involves patterning of at least part of the solid film formed. In this step, the physical dimensions and locations of final devices may be defined. The patterning is performed in accordance with a predetermined pattern which defines distinct features which are to be formed into the underlying substrate.

In one embodiment of the invention, the patterning creates the organic resist on the surface of the cooled substrate. The patterning may be performed by electron beam lithography, i.e. by exposing selected portions of the solid film to at least one electron beam. Other suitable techniques may also involve extreme ultraviolet (EUV) lithography or scanning probe microscope lithography techniques such as scanning tunnelling microscope.

An electron beam is considered a stable and well-focused beam of electrons with a high beam current and high energy. The electron beam may change the chemical structure and thereby the chemical composition of the exposed regions of the solid film. According to the invention, the solid film interacts with energetic electrons in a way so that the resulting product, i.e. the organic resist, remains essentially intact and stable under ambient conditions, i.e. when the organic resist is brought to for example room temperatures. The electron energy may be between 1 keV and 30 keV. There are also secondary electrons generated through in-elastic electron matter interactions. The secondary electrons may have an energy up to 50 eV. Both energies need to be larger than the few eV what is needed to ionize electrons in the outer shell in most atoms comprised in the solid film.

Typically, the number of electrons per unit surface which are required to expose the solid film, the so-called clearance dose, may be less than 50 μC/cm2. This dose is at least four times smaller than that required for standard, commercially used patterning. The sensitivity of the solid film may be higher as the ionization cross section (Table 1) given by the Bethe equation is also higher. The sensitivity of the solid film also depends on whether or not the solid film reacts in an avalanche chain reaction initiated by a single electron. Since the clearance dose is typically very low, the substrate under the solid film will not be damaged during the patterning process.

Electron beam writing time depends on a number of parameters such as a dose, area to be exposed and an electron beam current. As mentioned above, typically the dose is four times lower than that required for standard electron beam exposure. Therefore, the writing time is expected to be at least four times shorter than the time of a standard beam exposure.

The organic resist is created through a chemical reaction between the molecules comprised in the solid film and the electron beam while the solid film being kept in a high vacuum chamber at low temperature. Namely, an energetic electron beam locally changes the chemical properties and structure of the solid film thereby changing the chemical composition of the exposed regions of the solid film, creating tight bonds between the atoms comprised in the solid film, thereby forming the organic resist. Typically, the molecules comprised in the solid film react in an avalanche chain reaction initiated by a single electron creating free radicals which further react with each other in a radical polymerization reaction.

As previously addressed, the organic resist created may remain essentially intact when being exposed to ambient conditions thanks to tight chemical bonds formed between the atoms comprised in the solid film while the unexposed parts of the solid film will sublimate. Ambient conditions may typically refer to a normal, uncontrolled atmospheric pressure, room temperature and normal humidity values. These conditions may typically be fulfilled as soon as the sample is withdrawn from the vacuum chamber, i.e. taken outside the vacuum chamber.

As previously addressed, the organic resist created may be used as a mask for creating semiconductor structures and/or semiconductor devices. The semiconductor structures and/or the semiconductor devices may be created in either the underlying substrate or in another solid film being positioned between the solid structure and the substrate.

A roughness of the edges of the created organic resist may be less than 10 nm, such as less than 8 nm, such as less than 6 nm, such as less than 4 nm, such as less than 2 nm, such as less than 1 nm.

A half pitch of the created organic resist may be less than 50 nm, such as less than 40 nm, such as less than 30 nm, such as less than 20 nm, such as less than 10 nm. Half pitch or technology node is a measure for how densely devices can be packed together, i.e. it determines half the distance between the two identical patterns. By obtaining that the half pitch is less than 10 nm and the LER is smaller than 1 nm, the smallest features to be achieved are also smaller than 10 nm. LER may be highly dependent on the molecular weight of the vapour used. The interaction between the electron beam and the solid film determines the smallest pattern, and it depends on the forward scattering angle of electrons upon impact with the solid film substance, solid film thickness, sample temperature, penetration depth of energetic electrons, etc.

The semiconductor structures and/or the semiconductor devices may be transferred to the underlying substrate or solid film using, for example, an etching process, such as reactive ion etching, inductively coupled plasma reactive ion etching, ion sputtering and ion beam milling. The semiconductor structures and/or the semiconductor devices may also be slightly etched during the transfer process. The ratio of the substrate etch rate to the solid film consumption rate defines the etch selectivity, and may be optimized through carefully tuning parameters such as sample temperature, gas combinations and flow, and ion beam power. The etch selectivity between patterned organic resist and the substrate may be larger than 1:5.

The final step involves the removal of the organic resist created which was only slightly etched during the transfer process. The organic resist may be removed without harming the underlying substrate. The result is semiconductor structures and/or the semiconductor devices which may be functional devices.

### BRIEF DESCRIPTION OF THE DRAWINGS

The invention will now be described in further details with reference to the accompanying drawings, in which:

FIG. 1 illustrates a formation of an organic resist on a provided substrate,

FIG. 2 illustrates a vacuum chamber for a solid film formation and subsequent EBL patterning,

FIG. 3 illustrates a use of an organic resist as a mask for transferring structures to the underlying substrate,

FIG. 4 illustrates a 3-step manufacturing process for manufacturing a 3D solid structure,

FIG. 5 illustrates a 2-step manufacturing process for manufacturing a 3D solid structure, and

FIG. 6 shows in a) AFM profiles and in b) a SEM picture of silicon nanowires.

While the invention is susceptible to various modifications and alternative forms, specific embodiments have been shown by way of example in the drawings and will be described in detail herein. It should be understood, however, that the following description relates to examples of embodiments, and the invention is not intended to be limited to the particular forms disclosed. Rather, the invention covers all modifications, equivalents, and alternatives falling within the spirit and scope of the invention as defined by the appended claims. Furthermore, all the drawings are not to scale, and therefore any ratio extracted from the drawings is not relevant.

### DETAILED DESCRIPTION OF THE INVENTION

In its most general aspect, the present invention relates to the formation of a solid structure on a surface of a cooled substrate. The solid structure formed on the surface of the cooled substrate remains essentially intact when the substrate is brought from the cooled state to ambient temperatures. Preferably, the solid structure involves an organic resist that may be used as a mask for creating semiconductor structures and/or semiconductor devices.

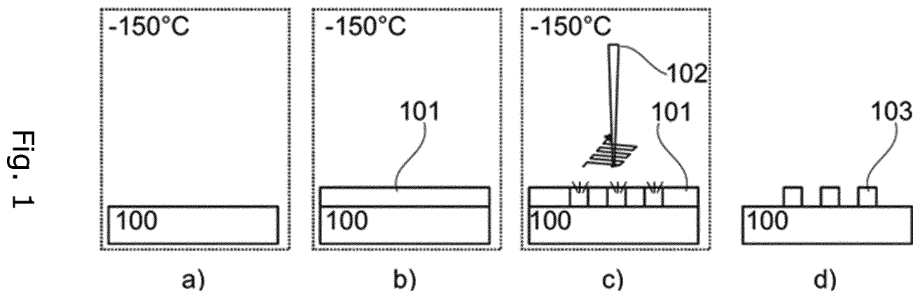

FIG. 1 illustrates a step by step process of the formation of the solid structure. FIG. 1a illustrates a substrate 100 which is provided in a high vacuum chamber and which is cooled down to a temperature of for example 110 K. In the next step a vapour which is introduced into the vacuum chamber is condensed when it gets in contact with the surface of the cooled substrate.

A potential candidate for the vapour is to be condensable under certain circumstances. Typically, the vapour comprises molecules with a molecular mass smaller than 100 Daltons. The vapour may be created from one of the following condensable chemical compounds: common gasses such as carbon dioxide, ammonia, sulfur dioxide or nitrous oxide; noble gases such as xenon; alkanes such as isobutene, heptane, nonane, decane; alcohols such as ethanol and isopropanol; organic solvents such as acetonitrile, chloroform, ethyl acetate, anisole-jenny, anisole or 1.4 dichlorobenzene; organics such as sulfur trioxide or naphthalene; monomers such as styrene.

The condensed vapour forms a solid film 101 as illustrated in FIG. 1b. FIG. 1c illustrates exposure of selected portions of the solid film 101 to three electron beams 102 in order to form solid structures in the form of an organic resist on the surface of the cooled substrate in accordance with a predetermined pattern. The exposure to the electron beams is performed in the vacuum chamber at low temperatures. An energetic electron beam locally changes the chemical properties of the solid film 101 whereby the organic resist is formed.

The organic resist is created through a chemical reaction between the solid film 101 and the electron beam 102. Namely, an energetic electron beam 102 locally changes the chemical properties and structure of the solid film 101 thereby changing the chemical composition of the exposed regions of the solid film 101 forming the organic resist.

Once the exposure of the solid film 101 is completed, the substrate, and thereby also the organic resist, is exposed to ambient conditions. The solid film 101 acts as a negative resist, i.e. parts of the solid film which were not exposed to the electron beams will sublimate, i.e. will be removed, while the exposed parts 103 will remain essentially intact thanks to tight chemical bonds formed between the atoms comprised in the solid film, thereby forming the organic resist 103 as illustrated in FIG. 1d. The organic resist 103 may then be used as a mask for creating semiconductor structures and/or semiconductor devices in the substrate 100.

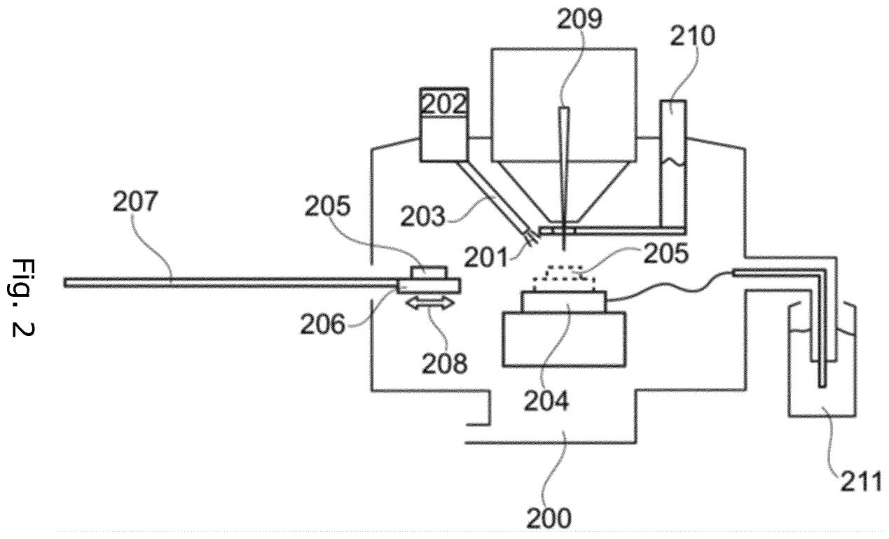

FIG. 2 illustrates a vacuum chamber 200 together with a majority of additional features required for the creation of the solid structure. A vapour 201 to be condensed is stored in a vapour chamber 202 and may be introduced into the vacuum chamber 200 through a nozzle 203 mounted above a cryostage 204 and deposited ballistically onto a cold sample 205. The sample is placed onto a sample holder 206 which is connected to a sample transfer arm 207. The sample 205 can be moved inside the vacuum chamber via the sample transfer arm 207. Using the same arm, the sample 205 can be withdrawn from the vacuum chamber, as the arm can be moved back and forth, as indicated by the arrow 208. After the vapour is condensed onto the sample, the solid film created is exposed to at least one electron beam 209 and the solid film is patterned in accordance with a predetermined pattern. The vacuum chamber and the cryostage are cooled by a liquid-nitrogen dewars 210, 211.

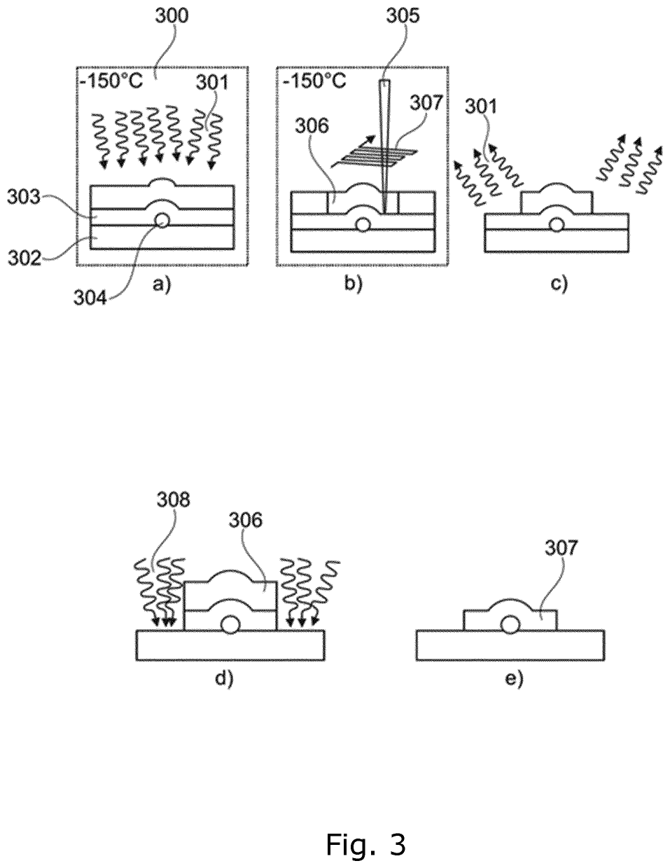

FIG. 3 illustrates a use of the organic resist as a mask for transferring structures to the underlying substrate. In a first step, shown in FIG. 3a, which is performed in a vacuum chamber 300, a vapour 301 is condensed onto a cooled substrate. In this case, the substrate is nonplanar, consisting of a base 302, what may be silicon-on-insulator, a metal layer 303, and a carbon nanotube 304. The next step is exposing the solid film to an electron beam 305, as shown in FIG. 3b, where an organic resist 306 is formed in accordance with a predetermined pattern 307. This step is also performed in the vacuum chamber 300. When the entire structure is taken out from the vacuum chamber to ambient conditions, unexposed parts of the solid film will sublimate, as shown in FIG. 3c. Now, the organic resist 306 may serve as a mask for transferring structures to the underlying metal layer 303 using for example an etching process, such as reactive ion etching 308, as illustrated in FIG. 3d. A small portion of the organic resist 306 is etched away as well during the removal of the underlying metal layer 303. The final step involves the removal of the remaining part of the organic resist 306 The result is a final structure 307, shown in FIG. 3e, which may be a final functional semiconductor device.

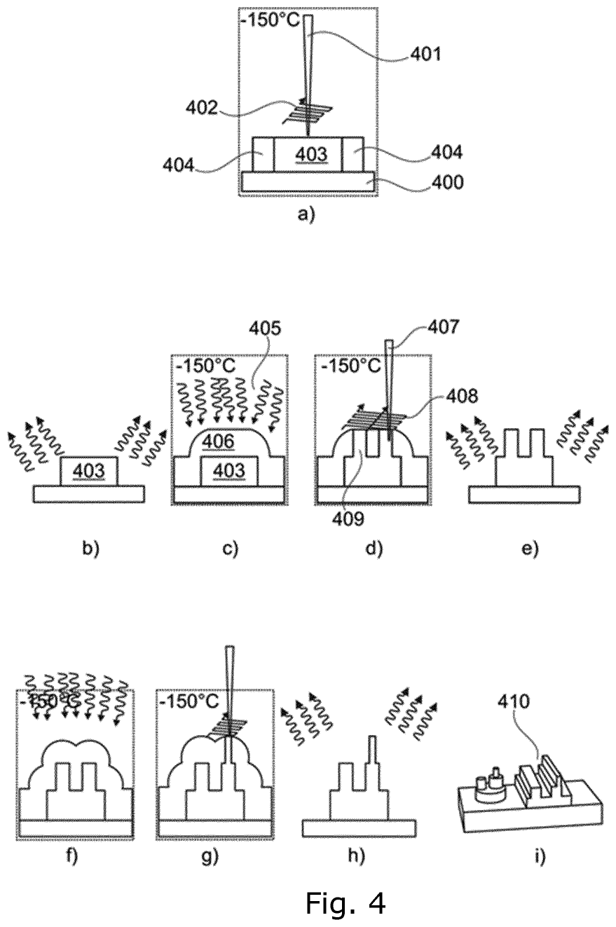

FIG. 4 illustrates how printing of 3D nano-patterns may be performed. Firstly, a solid film 404 is created in a vacuum chamber by condensing a vapour (not shown) onto a substrate 400 and exposing the solid film 404 to electron beams 401 as shown in FIG. 4a. In accordance with a first pattern 402, a first solid structure 403 is formed. Unexposed parts of the solid film 404 will evaporate when exposed to ambient conditions, while the first solid structure 403 will remain intact, as it is shown in FIG. 4b. The next step in the 3D nano-printing process, cf. FIG. 4c, is performed in the vacuum chamber where the vapour 405 is condensed onto the first solid structure 403 and the substrate 400, forming a second solid film 406. FIG. 4d illustrates exposure of the second solid film 406 to the electron beams 407 in accordance with a second pattern 408 whereby a second solid structure 409 is formed. When the structure shown in FIG. 4d is brought to room temperature, the unexposed regions of the solid film 406 sublimate, cf. FIG. 4e. By repeating steps shown in FIGS. 4c-4e additional structures may be provided, cf. FIGS. 4f-4h, whereby advanced 3D structures 410, cf. FIG. 4i, may be formed.

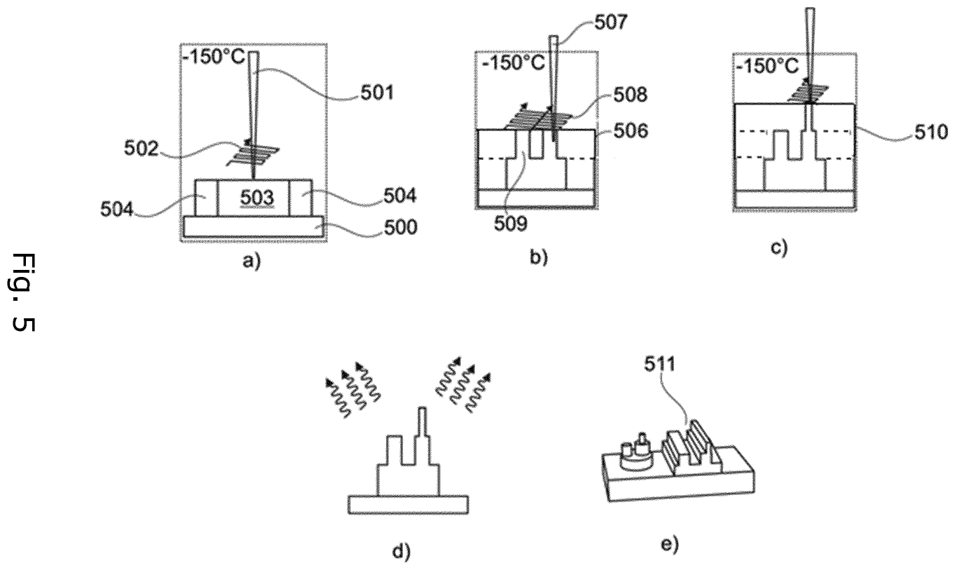

FIG. 5 illustrates another way of 3D nano-patterns printing. Firstly, a solid film 504 is created in a vacuum chamber by condensing a vapour (not shown) onto a substrate 500 and exposing the solid film 504 to electron beams 501 as shown in FIG. 5a. In accordance with a first pattern 502, a first solid structure 503 is formed. The next step in the 3D nano-printing process, cf. FIG. 4b, is also performed in the vacuum chamber where the vapour is condensed onto the first solid structure 503 and the solid film 504, forming a second solid film 506. FIG. 5b also illustrates exposure of the second solid film 506 to the electron beams 507 in accordance with a second pattern 508 whereby a second solid structure 509 is formed. By repeating steps shown in FIG. 5b additional structures may be provided, cf. FIG. 5c. When the structure shown in FIG. 5c is brought to room temperature, the unexposed regions of the solid film 510 sublimate cf. FIG. 5d. After this sublimation, advanced 3D structures 511, cf. FIG. 5e, may be formed.

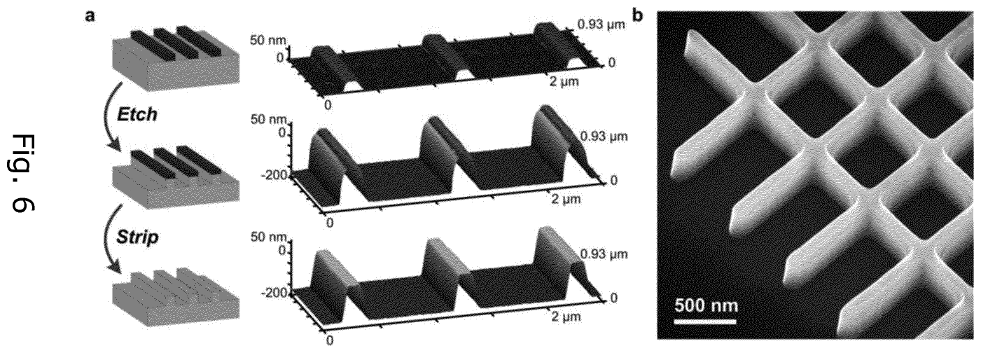

FIG. 6a shows fabrication of silicon nanowires by plasma etching in that FIG. 6a shows AFM profiles evolution of organic ice resist lines on a silicon substrate at three different steps during the etch process: as deposited (upper profile), after silicon etch (middle profile), and after removal (lower profile) of the residual organic ice resist. The etch selectivity between patterned organic ice resist and silicon is 1:6. FIG. 6b shows a SEM view of 400-nm-tall silicon fins made with organic ice resist and plasma etching.

1. A method for creating an organic resist on a surface of a cooled substrate, the method comprising the steps of
a) condensing a vapour into a solid film on the surface of the cooled substrate;
b) patterning at least part of the solid film by exposing selected portions of said solid film to at least one electron beam thereby creating the organic resist on the surface of the cooled substrate in accordance with a predetermined pattern; wherein the created organic resist remains essentially intact at ambient conditions; and
c) using the created organic resist as a mask for creating semiconductor structures and/or semiconductor devices.

2. A method according to claim 1, wherein the semiconductor structures and/or the semiconductor devices are created in the underlying substrate.

3. A method according to claim 2, wherein the semiconductor structures and/or the semiconductor devices are created in the underlying substrate using an etching process, such as reactive ion etching.

4. A method according to claim 2, further comprising the step of removing the organic resist.

5. A method according to claim 1, wherein the substrate comprises a semiconductor substrate, such as a silicon substrate.

6. A method according to claim 1, wherein the vapour is created from one or more of the following classes of chemicals: hydrocarbon C6-C16, sulfur containing compounds, halogen containing compounds, oxygen containing compounds, nitrogen containing compounds, monomers, and ALD and CVD precursors for metallic layers.

7. A method according to claim 1, wherein the substrate, during exposure of the solid film, is cooled to temperatures below 200 K, such as below 170 K, such as below 150 K, such as below 130 K, such as below 110 K, such as below 90 K, such as around 70 K.

8. A method according to claim 1, wherein the patterning of the solid film is performed by electron beam lithography.

9. A method according to claim 1, wherein the roughness of the edges of the created semiconductor structures and/or semiconductor devices is less than 10 nm, such as less than 8 nm, such as less than 6 nm, such as less than 4 nm, such as less than 2 nm, such as less than 1 nm.

10. A method according to claim 1, wherein a half pitch of the created semiconductor structures and/or semiconductor devices is less than 50 nm, such as less than 40 nm, such as less than 30 nm, such as less than 20 nm, such as less than 10 nm.

11. A method according to claim 1, wherein the cooled substrate is arranged on a cryosystem being arranged in a high vacuum chamber.

12. A method according, to claim 11, wherein the vapour is introduced into the high vacuum chamber via a gas injection system.

13. A method according to claim 11, wherein the solid film has a vapour pressure being smaller than the pressure in the high vacuum chamber in order to prevent sublimation.

14. A method according to claim 1, wherein the vapour comprises molecules with a molecular mass smaller than 100 Daltons.
